(19) United States
(12) Patent Application Publication
(10) Pub. No.: US 2024/0186359 A1
(43) Pub. Date: Jun. 6, 2024

(54) IMAGE SENSOR AND MANUFACTURING METHOD OF THE SAME

(71) Applicant: SAMSUNG ELECTRONICS CO., LTD., SUWON-SI (KR)

(72) Inventors: Jungwook LIM, Suwon-si (KR); Younggu JIN, Suwon-si (KR)

(21) Appl. No.: 18/244,342

(22) Filed: Sep. 11, 2023

(30) Foreign Application Priority Data
Dec. 6, 2022 (KR) 10-2022-0168869

(51) Int. Cl. H01L 27/146

(52) U.S. Cl. CPC H01L 27/14643; H01L 27/14612; H01L 27/14627; H01L 27/1463; H01L 27/14636; H01L 27/14685

(57) ABSTRACT

An image sensor includes: a pixel array including a plurality of pixels, wherein each of the pixels includes a first photodiode, a second photodiode, a first transmission gate, a second transmission gate, and a plurality of active regions; and a logic circuit configured to control the pixels. The plurality of active regions include a first active region, a second active region and a third active region. The first active region is disposed adjacent to the first transmission gate. The second active region is disposed adjacent to the second transmission gate. The third active region is electrically connected to the second active region. The first active region and the second active region are disposed on a main substrate including the first and second photodiodes. The third active region is disposed on a sub-substrate attached to the main substrate.

### CROSS-REFERENCE TO RELATED APPLICATION

This application claims priority under 35 U.S.C. § 119 to Korean Patent Application No. 10-2022-0168869 filed on Dec. 6, 2022, in the Korean Intellectual Property Office, the disclosure of which is incorporated by reference herein in its entirety.

### TECHNICAL FIELD

The present inventive concept relates to an image sensor and a manufacturing method of the same.

### DISCUSSION OF THE RELATED ART

Generally, the image sensor is a semiconductor-based sensor for receiving light and generating an electrical signal, and may include a pixel array, which has a plurality of pixels, and a logic circuit, which is for driving the pixel array and generating an image. Each of the pixels may include a photodiode and a pixel circuit for converting electric charges that are generated from the photodiode into an electrical signal. To increase the performance of such an image sensor, a structure in which each of a plurality of pixels includes a plurality of photodiodes has been under development. When each of the plurality of pixels includes the plurality of photodiodes, blocking charge transfer between the photodiodes become desirable.

### SUMMARY

According to an example embodiment of the present inventive concept, an image sensor includes: a pixel array in which a plurality of pixels are arranged, wherein each of the plurality of pixels includes a first photodiode, a second photodiode, a first transmission gate, a second transmission gate, and a plurality of active regions; and a logic circuit configured to control the plurality of pixels, wherein a light receiving area of the first photodiode is larger than a light receiving area of the second photodiode, the plurality of active regions include a first active region, a second active region and a third active region, wherein the first active region is disposed adjacent to the first transmission gate, wherein the second active region is disposed adjacent to the second transmission gate, wherein the third active region is electrically connected to the second active region by a wiring pattern, and the first active region and the second active region are disposed on a main substrate, which includes the first photodiode and the second photodiode, and the third active region is disposed on a sub-substrate that is attached to the main substrate.

According to an example embodiment of the present inventive concept, an image sensor includes: a main substrate including a plurality of pixel regions and a plurality of photodiodes, wherein the plurality of pixel regions is separated from each other by a pixel separation film, and the plurality of photodiodes is disposed in the plurality of pixel regions; a sub-substrate disposed on a first surface of the main substrate; an optical region disposed on a second surface of the main substrate and including a plurality of color filters and a plurality of micro lenses, wherein some transistor among a plurality of transistors included in each of the plurality of pixel regions are disposed on the main substrate, and the other transistors among the plurality of transistors are disposed on the sub-substrate, and the some transistors and the other transistors do not overlap each other in a direction substantially perpendicular to the first surface of the main substrate.

According to an example embodiment of the present inventive concept, a manufacturing method of an image sensor includes: forming a pixel separation film, which is configured to separate a plurality of pixel regions, on a main substrate; forming a plurality of photodiodes on the main substrate; attaching a sub-substrate to the main substrate; removing a partial region of the sub-substrate, forming a plurality of semiconductor elements on the main substrate and the sub-substrate; and forming a plurality of color filters and a plurality of micro lenses on the main substrate.

### BRIEF DESCRIPTION OF DRAWINGS

The above and other aspects of the present inventive concept will become more apparent by describing in detail example embodiments thereof, with reference to the accompanying drawings, in which:

FIG. 1 is a block diagram schematically illustrating an image sensor according to an example embodiment of the present inventive concept;

FIG. 2 is a diagram schematically illustrating a pixel circuit of each of a plurality of pixels included in an image sensor according to an example embodiment of the present inventive concept;

FIG. 3 is a diagram schematically illustrating pixels included in an image sensor according to an example embodiment of the present inventive concept;

FIG. 4 is a diagram schematically illustrating pixels included in an image sensor according to an example embodiment of the present inventive concept;

FIG. 5 is a cross-sectional view illustrating a cross-section taken along line I-I′ of FIG. 4;

FIG. 6 is a diagram schematically illustrating pixels the included in an image sensor according to an example embodiment of the present inventive concept;

FIG. 7 is a diagram schematically illustrating pixels included in an image sensor according to an example embodiment of the present inventive concept;

FIG. 8 is a cross-sectional view illustrating a cross-section taken along line II-II′ of FIG. 7;

FIG. 9 is a diagram schematically illustrating pixels included in an image sensor according to an example embodiment of the present inventive concept;

FIG. 10 is a cross-sectional view illustrating a cross-section taken along line III-III′ of FIG. 9;

FIGS. 11 and 12 are simply diagrams illustrating pixels included in an image sensor according to an example embodiment of the present inventive concept;

FIG. 13 is a flowchart illustrating a manufacturing method of an image sensor according to an example embodiment of the present inventive concept;

FIGS. 14, 15, 16, 17, 18, 19, 20, 21, 22 and 23 are intermediate steps illustrating the manufacturing method of an image sensor according to an example embodiment of the present inventive concept; and

FIG. 24 is a diagram schematically illustrating pixels included in an image sensor according to an example embodiment of the present inventive concept.

### DETAILED DESCRIPTION OF THE EMBODIMENTS

Hereinafter, example embodiments of the present inventive concept will be described with reference to the accompanying drawings.

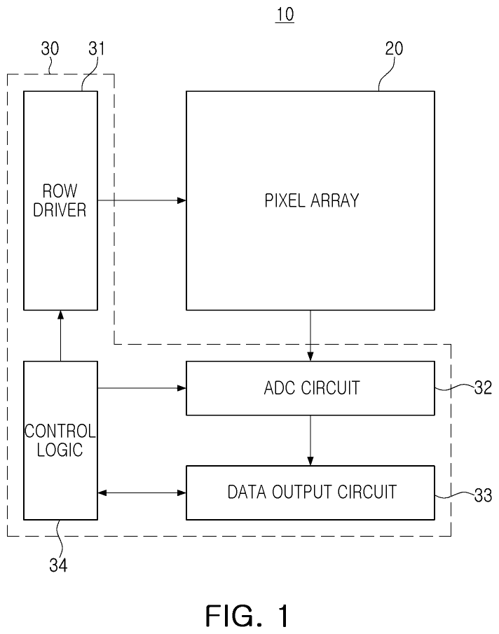

FIG. 1 is a block diagram schematically illustrating an image sensor according to an example embodiment of the present disclosure.

Referring to FIG. 1, an image sensor 10 may include a pixel array 20 and a peripheral circuit 30.

The pixel array 20 may include a plurality of pixels arranged in an array that is formed along a plurality of rows and a plurality of columns. Each of the plurality of pixels may include at least one photoelectric conversion element, which is for generating electric charges in response to light, and a pixel circuit, which is for generating a voltage signal corresponding to the electric charges that are generated from the photoelectric conversion element. The photoelectric conversion element may include a photodiode, which is formed of a semiconductor material, and/or an organic photodiode, which is formed of an organic material.

For example, the pixel circuit may include a floating diffusion region, a transmission transistor, a reset transistor, a switch transistor, a source-follower transistor, and a select transistor. The configurations of the pixels may vary according to example embodiments of the present inventive concept. For example, each of the pixels may include an organic photodiode including an organic material, or may be implemented as digital pixels. When the pixels are implemented as the digital pixels, each of the pixels may include an analog-to-digital converter for outputting a digital pixel signal.

The peripheral circuit 30 may include circuits for controlling the pixel array 20. For example, the peripheral circuit 30 may include a row driver 31, an analog-to-digital converter (ADC) circuit 32, a data output circuit 33, and a control logic 34. The row driver 31 may drive the pixel array 20 in units of row lines. For example, the row driver 31 may generate a transmission control signal for controlling the transmission transistor of the pixel circuit, a reset control signal for controlling the reset transistor, a select control signal for controlling the select transistor, and a switch control signal for controlling the switch transistor, and may input the generated signals into the pixel array 20 in units of row lines.

An ADC circuit 32 includes a plurality of correlation double samplers and a plurality of counters, and the correlation double samplers may be connected through pixels and column lines. The correlation double samplers may read voltage signals through the column lines from pixels connected to a row line selected by a row line select signal of the row driver 31. The counter included in the ADC circuit 33 may convert an output of the correlation double sampler into a digital pixel signal. For example, a latch or a buffer circuit and an amplification circuit capable of temporarily storing the digital pixel signal may be connected to an output terminal of the analog-to-digital converter. The control logic 34 may include a timing controller for controlling operation timings of the row driver 31, the ADC circuit 32, and the data output circuit 33.

Pixels PX disposed at the same position in a horizontal direction among the pixels PX may share the same column line. For example, pixels PX disposed at the same position in a vertical direction are simultaneously selected by the row driver 31 and may output pixel signals through column lines. In an example embodiment of the present inventive concept, a plurality of correlation double samplers included in the ADC circuit 32 may simultaneously receive the voltage signal from pixels selected by the row driver 31 through the column lines. For example, the plurality of correlation double samplers may sequentially receive a reset voltage and a pixel voltage from the pixels, and the pixel voltage may be a voltage at which electric charges generated from a photodiode of each of the pixels are reflected in the reset voltage.

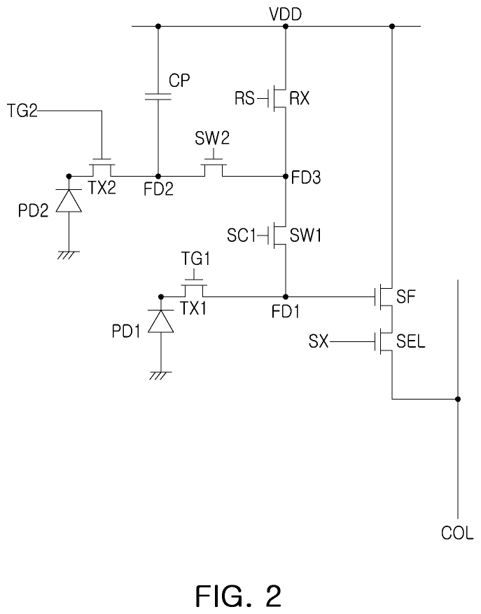

FIG. 2 is a diagram schematically illustrating a pixel circuit of each of a plurality of pixels included in an image sensor according to an example embodiment of the present inventive concept.

Referring to FIG. 2, each of a plurality of pixels according to an example embodiment of the present inventive concept may include a first photodiode PD1, a second photodiode PD2, a first transmission transistor TX1, a second transmission transistor TX2, a plurality of switch transistors SW1 and SW2, a reset transistor RX, a source-follow transistor SF, and a select transistor SEL. The first photodiode PD1 may be connected to a first floating diffusion region FD1 through the first transmission transistor TX1, and the second photodiode PD2 may be connected to a second floating diffusion region FD2 through the second transmission transistor TX2.

Each of the reset transistor RX and the source-follower transistor SF may be connected to a power node supplying a power voltage VDD. A gate of the source-follower transistor SF may be connected to the first floating diffusion region FD1, and the select transistor SEL may be connected to and positioned between the source-follower transistor SF and the column line COL.

The first switch transistor SW1 may be connected to and positioned between the reset transistor RX and the first floating diffusion region FD1, and a node between the first switch transistor SW1 and the reset transistor RX may be a third floating diffusion region FD3. The second switch transistor SW2 may be connected to and positioned between the second floating diffusion region FD2 and the third floating diffusion region FD3. A capacitor element CP may be connected to and positioned between the second floating diffusion region FD2 and the power node.

When the operation of the image sensor is initiated, a logic circuit may reset voltages of the floating diffusion regions FD1 to FD3 by turning on the first transmission transistor TX1, the second transmission transistor TX2, the reset transistor RX, and the switch transistors SW1 and SW2. For example, the voltages of the floating diffusion regions FD1 to FD3 may be reset to the power voltage VDD. The logic circuit may turn on the select transistor SEL to detect voltages of the reset floating diffusion regions FD1 to FD3 as reset voltages. During the reset operation, electric charges of the first photodiode PD1 and the second photodiode PD2 may be removed.

When the voltages of the floating diffusion regions FD1 to FD3 are reset, the logic circuit may turn off the first transmission transistor TX1, the second transmission transistor TX2, and the reset transistor RX. During an exposure time when the first transmission transistor TX1, the second transmission transistor TX2, and the reset transistor RX are turned off, the first photodiode PD1 and the second photodiode PD2 may be exposed to light to generate electric charges.

During the exposure time, an operation of turning on/off the switch transistors SW1 and SW2 may be determined as necessary. For example, when the switch transistors SW1 and SW2 are turned on during the exposure time, the floating diffusion regions FD1 to FD3 are electrically connected to each other, which may thus reduce a conversion gain of the image sensor. In addition, when the switch transistors SW1 and SW2 are turned off during the exposure time, the floating diffusion regions FD1 to FD3 may be separated or disconnected from each other, which may thus increase the conversion gain of the image sensor.

For example, the logic circuit of the image sensor may obtain a first pixel signal under a high conversion gain condition in which the switch transistors SW1 and SW2 are turned off in each of the plurality of pixels during one frame period, and may then obtain a second pixel signal under a low conversion gain condition in which the switch transistors SW1 and SW2 are turned on. The logic circuit may generate an image having a high dynamic range using the pixel signals obtained from each of the high and low conversion gain conditions.

According to an example embodiment of the present inventive concept, the logic circuit may obtain the first pixel signal and the second pixel signal from the first photodiode PD1, and may obtain the first pixel signal and the second pixel signal from the second photodiode PD2. Accordingly, it is desirable to effectively separate the electric charge generated from the first photodiode PD1 and the electric charge generated from the second photodiode PD2 from each other so that the electric charges are not combined with each other.

For example, in each of the plurality of pixels, an internal separation film may be formed between the first photodiode PD1 and the second photodiode PD2 to prevent the electric charges from being transferred between the first photodiode PD1 and the second photodiode PD2. However, according to a layout of each of the plurality of pixels, an active region that is disposed on the second photodiode PD2 may be connected to another active region that is disposed on the first photodiode PD1 by a wiring pattern and may provide the second floating diffusion region FD2. In this case, the electric charges generated from the first photodiode PD1 may flow into the second photodiode PD2 along the wiring pattern. In addition, the electric charges generated from the second photodiode PD2 may flow into the first photodiode PD1 along the wiring pattern.

Depending on the layout of each of the plurality of pixels, the active region disposed on the second photodiode PD2 might not be directly connected to another active region that is disposed on the first photodiode PD1 by the wiring pattern. However, even in this case, the electric charges generated from the first photodiode PD1 may flow into the second floating diffusion region FD2 and/or the third floating diffusion region FD3 through leakage currents of the switch transistors SW1 and SW2.

In an example embodiment of the present inventive concept, some transistors among a plurality of transistors included in a pixel circuit, for example, the switch transistors SW1 and SW2, may be formed a sub-substrate different from a main substrate. The sub-substrate may be a substrate attached to a first surface of the main substrate on which the first transmission transistor TX1 and the second transmission transistor TX2 are disposed, and may be a silicon on insulator (SOI) substrate. Accordingly, the sub-substrate may include an insulating layer disposed between the main substrate and a region in which the switch transistors SW1 and SW2 are formed, and may block the electric charge transfer between the first photodiode PD1 and the second photodiode PD2 through at least one of the switch transistors SW1 and SW2.

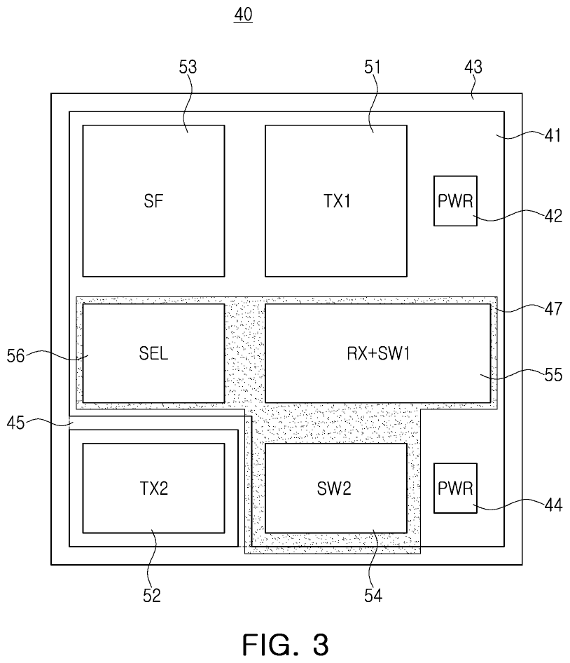

FIG. 3 is a diagram schematically illustrating pixels included in an image sensor according to an example embodiment of the present inventive concept.

FIG. 3 may be a diagram schematically illustrating a layout of a pixel 40 in the image sensor according to an example embodiment of the present inventive concept. Referring to FIG. 3, the pixel 40 may be separated from other peripheral pixels by a pixel separation film 43 that is formed on a main substrate 41. In addition, the pixel 40 may include a first region and a second region that are separated from each other by an internal separation film 45. The first region may have an area larger than that of the second region. A first photodiode may be formed in the first region, and a second photodiode may be formed in the second region. Accordingly, a light receiving area of the first photodiode may be larger than a light receiving area of the second photodiode.

The pixel 40 may include a plurality of transistors connected to the first photodiode and the second photodiode. For example, the pixel 40 may include a first transmission transistor TX1, a second transmission transistor TX2, a source-follower transistor SF, a select transistor SEL, a reset transistor RX, a first switch transistor SW1, and a second switch transistor SW2. The pixel 40 includes a plurality of active regions, and the plurality of active regions may be coupled to a plurality of gates and may provide a plurality of transistors. At least one of the plurality of active regions may provide a power region 44 that receives a power voltage.

As illustrated in FIG. 3, the plurality of transistors may be disposed in a plurality of element regions 51 to 56. An element separation film may be formed of an insulating material and may be disposed between the plurality of element regions 51 to 56. In an example embodiment that is illustrated in FIG. 3, the first switch transistor SW1 and the reset transistor RX are disposed in the fifth element region 55 and may share one of the active regions. However, this is an example embodiment, and the shapes and positions of the plurality of element regions 51 to 56 in which the plurality of transistors are disposed may be variously changed according to a layout of the pixel 40.

Referring to FIG. 3, a sub-substrate 47 is attached to the main substrate 41, and some transistors among a plurality of transistors may be formed on the sub-substrate 47. In an example embodiment illustrated in FIG. 3, the select transistor SEL, the reset transistor RX, the first switch transistor SW1, and the second switch transistor SW2 may be formed on the sub-substrate 47.

For example, a pixel circuit of the pixel 40 described with reference to FIG. 3 may be the same as that described with reference to FIG. 2. Accordingly, the second floating diffusion region may be formed in the second element region 52 in which the second transmission transistor TX2 is disposed. As illustrated in FIG. 2, the second floating diffusion region may be connected to one of the active regions of the second switch transistor SW2, and in the pixel 40 having the layout as illustrated in FIG. 3, one of the active regions disposed in the fourth element region 54 may be connected to an active region of the second element region 52 by the wiring pattern. For example, the second floating diffusion region may be directly connected to one of the active regions of the second switch transistor SW2, and one of the active regions disposed in the fourth element region 54 may be directly connected to an active region of the second element region 52.

Assuming that the fourth element region 54 exists in the main substrate 41, electric charges of the first photodiode formed below the fourth element region 54 may flow into the active region of the second element region 52 through the wiring pattern with one of the active regions of the fourth element region 54. Since the second photodiode is disposed below the second element region 52, the electric charges of the first photodiode may be transferred to the second photodiode, resulting in a decrease in a signal-to-noise ratio.

In an example embodiment of the present inventive concept, the fourth element region 54 may be formed on the sub-substrate 47 attached to the main substrate 41. The sub-substrate 47 may be an SOI substrate. A path through which the electric charges generated from the first photodiode are transferred to the second photodiode may be blocked by an insulating layer, which is included in the sub-substrate 47 and disposed adjacent to the main substrate 41. Accordingly, the signal-to-noise ratio of the image sensor may be improved.

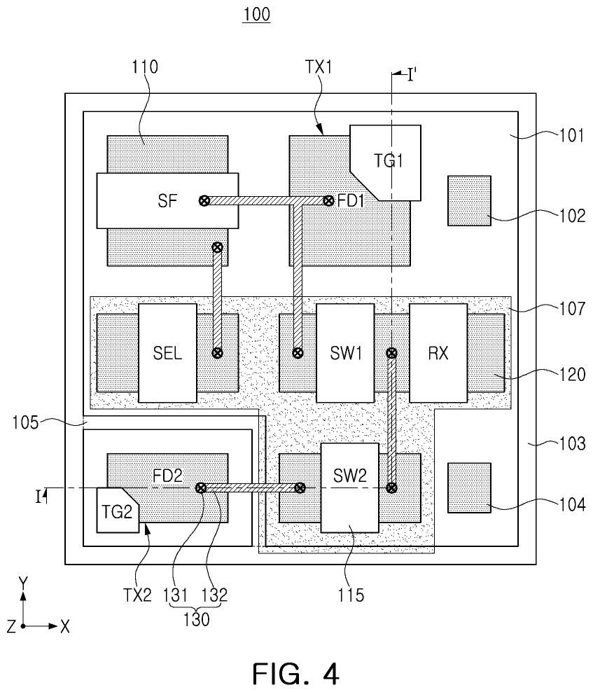

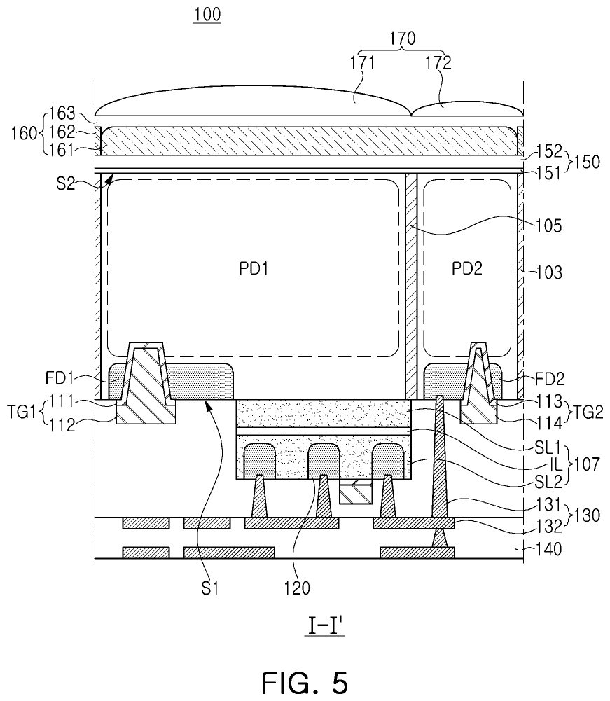

FIG. 4 is a diagram schematically illustrating pixels included in an image sensor according to an example embodiment of the present inventive concept, and FIG. 5 is a cross-sectional view illustrating a cross-section taken along line I-I′ of FIG. 4.

Referring to FIGS. 4 and 5, a pixel 100 of the image sensor according to an example embodiment of the present inventive concept may be separated from other peripheral pixels by a pixel separation film 103 that is formed on a main substrate 101 and that defines a plurality of pixel regions. The pixel 100 may include a first region and a second region separated from each other by an internal separation film 105. The first photodiode may be formed in the first region, and the second photodiode may be formed in the second region. A light receiving area of the first photodiode may be larger than a light receiving area of the second photodiode.

The pixel 100 may include a plurality of active regions 110 and 120 and a plurality of gates 115. Each of the plurality of gates 115 may provide a plurality of transistors along with at least one of the plurality of active regions 110 and 120. The plurality of transistors may include a first transmission transistor TX1, a second transmission transistor TX2, a source-follower transistor SF, a select transistor SEL, a reset transistor RX, a first switch transistor SW1, and a second switch transistor SW2.

A sub-substrate 107 may be attached to a first surface S1 of the main substrate 101. The sub-substrate 107 may be, for example, an SOI substrate, and in this case, an insulating layer included in the sub-substrate 107 may be disposed between transistors formed on the sub-substrate 107 and the first surface S1 of the main substrate 101. Referring to FIGS. 4 and 5, some transistors among the plurality of transistors may be disposed on the main substrate 101, and the other transistors may be disposed on the sub-substrate 107. At least a partial region of the sub-substrate 107 may be disposed to overlap the internal separation film 105.

Some transistors, which are disposed on the main substrate 101, and the other transistors, which are disposed on the sub-substrate 107, might not overlap each other in a direction (e.g., a Z-axis direction) substantially perpendicular to the first surface S1 of the main substrate 101. In other words, some transistors, which are disposed on the main substrate 101, and the other transistors, which are disposed on the sub-substrate 107, may be disposed at different positions from each other in a first direction (e.g., an X-axis direction) and a second direction (e.g., a Y-axis direction) so that they do not overlap each other in the direction (e.g., a Z-axis direction) that is substantially perpendicular to the first surface S1 of the main substrate 101. In an example embodiment illustrated in FIGS. 4 and 5, the first transmission transistor TX1, the second transmission transistor TX2, and the source-follower transistor SF may be disposed on the main substrate 101. In addition, the first switch transistor SW1, the second switch transistor SW2, the reset transistor RX, and the select transistor SEL may be disposed on the sub-substrate 107.

Among the plurality of active regions 110 and 120, the main active regions 110 formed in the main substrate 101 may provide active regions of the first floating diffusion region FD1, the second floating diffusion region FD2, and the source-follower transistor SF. In addition, the sub-active regions 120 that is formed on the sub-substrate 107 may provide active regions of the first switch transistor SW1, the second switch transistor SW2, the reset transistor RX, and the select transistor SEL.

A first transmission gate TG1 and a second transmission gate TG2 may be formed on the main substrate 101 along with the first floating diffusion region FD1 and the second floating diffusion region FD2. The first transmission gate TG1 and the second transmission gate TG2 may have a structure in which at least a portion thereof is embedded in the main substrate 101. Each of the first transmission gate TG1 and the second transmission gate TG2 may include transmission gate insulating layers 111 and 113 and transmission gate electrode layers 112 and 114.

A plurality of wiring patterns 130 including a contact 131 and a wiring 132 may be connected to the plurality of active regions 110 and 120 and the plurality of gates 115. The plurality of wiring patterns 130 may be covered by an interlayer insulating layer 140 that is disposed on the main substrate 101. For example, the interlayer insulating layer 140 may be disposed on the first surface S1 of the main substrate 101. For example, at least one capacitor element may be formed in the interlayer insulating layer 140, and the capacitor element may be connected to the second floating diffusion region FD2 through the plurality of wiring patterns 130.

In addition, an optical region may be disposed on a second surface S2 of the main substrate 101. The optical region may include a horizontal insulating layer 150, a color filter layer 160, and a micro lens 170. The horizontal insulating layer 150 includes a first horizontal insulating layer 151 and a second horizontal insulating layer 152. For example, the first horizontal insulating layer 151 may be in contact with the main substrate 101 and may be formed of a material having a higher dielectric constant than that of the second horizontal insulating layer 152. The first horizontal insulating layer 151 may have a thickness smaller than that of the second horizontal insulating layer 152, and a portion of defects of the main substrate 101 may be cured by the first horizontal insulating layer 151.

The color filter layer 160 may include a color filter 161, a filter separation film 162, and a planarization layer 163. The filter separation film 162 is disposed on the pixel separation film 103, and the color filter 161 may be arranged along the plurality of pixel regions by the filter separation film 162. For example, the filter separation film 162 may be disposed above the pixel separation film 103. The planarization layer 163 may be disposed on the color filter 161, and the micro lens 170 may be disposed on the planarization layer 163.

The micro lens 170 may refract light that is incident from the outside and may advance the refracted light to the color filter 161, and light of a specific wavelength band may be selectively incident on the first photodiode PD1 and the second photodiode PD2 by the color filter 161. The micro lens 170 may include a first micro lens 171, which is disposed above the first photodiode PD1, and a second micro lens 172, which is disposed above the second photodiode PD2. However, according to an example embodiment of the present inventive concept, one micro lens may be disposed on the planarization layer 163 to cover the first photodiode PD1 and the second photodiode PD2.

Referring to FIGS. 4 and 5, the plurality of active regions 110 and 120 may include a first active region and a second active region. The first active region may be disposed adjacent to the first transmission gate TG1 and may be configured to provide the first floating diffusion region FD1, and the second active region disposed adjacent to the second transmission gate TG2 and may be configured to provide the second floating diffusion region FD2. The second active region may be electrically connected to a third active region that is one of the active regions 120, which is formed on the sub-substrate 107, by at least one of the plurality of wiring patterns 130.

The third active region may be disposed on the first photodiode PD1. Accordingly, when the third active region is formed on the main substrate 101 rather than the sub-substrate 107, the electric charges generated from the first photodiode PD1 may flow into the second photodiode PD2 and the second active region configured to provide the second floating diffusion region FD2 through the third active region and the wiring pattern 130. In a readout operation of reading a pixel signal corresponding to the electric charges generated from the second photodiode PD2, the electric charge generated from the first photodiode PD1 may be reflected in the pixel signal as a noise component, thereby reducing the signal-to-noise ratio.

In an example embodiment of the present inventive concept, as the second active region and the third active region, which are directly connected to each other by the wiring pattern 130, are formed on the sub-substrate 107, the electric charges generated from the first photodiode PD1 may be prevented from flowing into the second photodiode PD2 and the second floating diffusion region FD2. The sub-substrate 107 may be an SOI substrate including a first semiconductor layer SL1, an insulating layer IL, and a second semiconductor layer SL2. Accordingly, by the insulating layer IL of the sub-substrate 107, the electric charge generated from the first photodiode PD1 might not flow into the third active region of the sub-substrate 107. An electric charge transfer path between the first photodiode PD1 and the second photodiode PD2 may be blocked, and in the readout operation of reading the pixel signal corresponding to the electric charges of each of the first photodiode PD1 and the second photodiode PD2, the effect of the electric charges generated from the other photodiodes may be minimized, thereby improving the signal-to-noise ratio of the image sensor.

In addition, in an example embodiment illustrated in FIGS. 4 and 5, the source-follower transistor SF may be formed on the main substrate 101. When the source-follower transistor SF is formed on the sub-substrate 107, the length of the wiring pattern 130 configured to connect the first floating diffusion region FD1 and the gate of the source-follower transistor SF to each other increases. With the increase in the length of the wiring pattern configured to connect the first floating diffusion region FD1 and the gate of the source-follower transistor SF to each other, a capacitance of the wiring pattern may be added to the first floating diffusion region FD1, thereby increasing a capacitance of the image sensor 100 and reducing a conversion gain of the image sensor 100. Accordingly, as illustrated in FIGS. 4 and 5, a decrease in the conversion gain of the image sensor 100 may be prevented by forming the source-follower transistor SF on the main substrate 101.

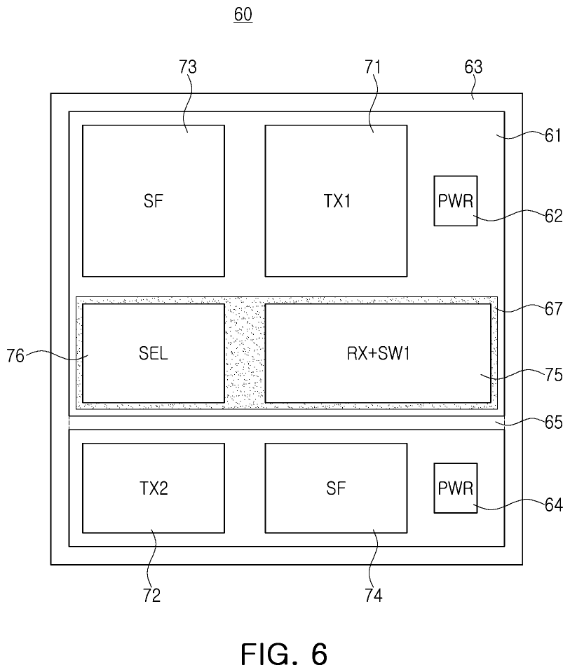

FIG. 6 is a diagram schematically illustrating pixels that are included in an image sensor according to an example embodiment of the present inventive concept.

FIG. 6 may be a diagram schematically illustrating a layout of a pixel 60 in an image sensor according to an example embodiment of the present inventive concept. Referring to FIG. 6, the pixel 60 may be formed on the main substrate 61 and separated from other peripheral pixels by a pixel separation film 63, which defines a plurality of pixel regions. In addition, the pixel 60 may include a first region and a second region separated from each other by an internal separation film 65. A first photodiode may be formed in the first region, and a second photodiode may be formed in the second region.

The pixel 60 may include a plurality of transistors connected to the first photodiode and the second photodiode and configured to provide a pixel circuit. For example, the plurality of transistors may include a first transmission transistor TX1, a second transmission transistor TX2, a source-follower transistor SF, a select transistor SEL, a reset transistor RX, a first switch transistor SW1, and a second switch transistor SW2. The plurality of transistors may be disposed in a plurality of element regions 71 to 76, and an element separation film may be formed between the plurality of element regions 71 to 76. In addition, at least one or more power regions 62 and 64 for supplying a power voltage may be disposed in the pixel 60.

Referring to FIG. 6, a sub-substrate 67 is attached onto the main substrate 61, and some transistors among a plurality of transistors may be formed on the sub-substrate 67. In an example embodiment illustrated in FIG. 6, the select transistor SEL, the reset transistor RX, and the first switch transistor SW1 may be formed on the sub-substrate 67, and the sub-substrate 67 might not overlap the internal separation film 65. For example, the sub-substrate 67 may be formed adjacent to the internal separation film 65.

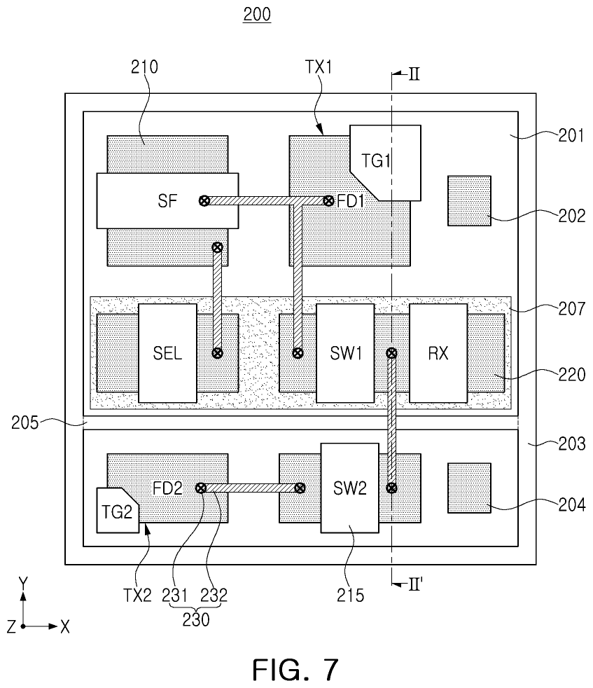

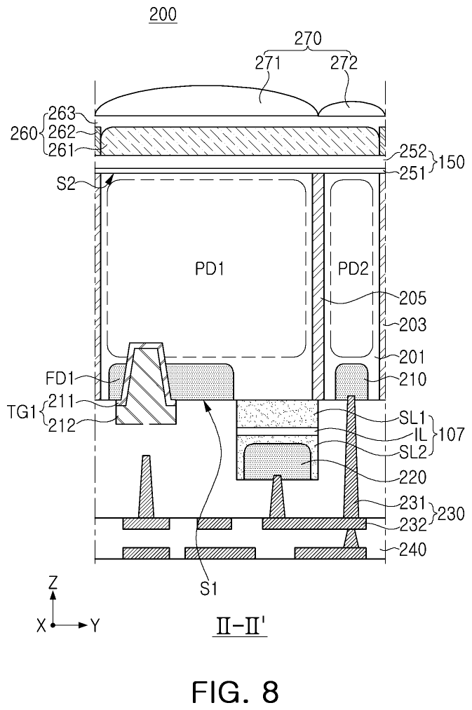

FIG. 7 is a diagram schematically illustrating pixels included in an image sensor according to an example embodiment of the present inventive concept, and FIG. 8 is a cross-sectional view illustrating a cross-section taken along line II-II′ of FIG. 7.

Referring to FIGS. 7 and 8, a pixel 200 of the image sensor according to an example embodiment of the present inventive concept may be separated from other peripheral pixels by a pixel separation film 203 that is formed on the main substrate 201. A plurality of pixel regions are defined by the pixel separation film 203, and a first photodiode PD1 and a second photodiode PD2 may be separated from each other by an internal separation film 205 that is disposed in the pixel 200. The pixel separation film 203 and the internal separation film 205 may be formed to a depth penetrating through the main substrate 201. For example, the pixel separation film 203 and the internal separation film 205 may completely penetrate the main substrate 201.

The pixel 200 may include a plurality of active regions 210 and 220 and a plurality of gates 215, and the plurality of gates 215 may provide a plurality of transistors along with the plurality of active regions 210 and 220. The plurality of transistors may include a first transmission transistor TX1, a second transmission transistor TX2, a source-follower transistor SF, a select transistor SEL, a reset transistor RX, a first switch transistor SW1, and a second switch transistor SW2.

A sub-substrate 207 may be attached to a first surface S1 of the main substrate 201. The sub-substrate 207 may be an SOI substrate. Referring to FIGS. 7 and 8, the first transmission transistor TX1, the second transmission transistor TX2, the source-follower transistor SF, and the second switch transistor SW2 may be formed on the main substrate 201. In addition, the first switch transistor SW1, the reset transistor RX, and the select transistor SEL may be formed on the sub-substrate 207. Since the sub-substrate 207 is the SOI substrate, an insulating layer may be disposed between the first switch transistor SW1, the reset transistor RX, and the select transistor SEL and the main substrate 201.

The main active regions 210 formed on the main substrate 201 may provide active regions of the first floating diffusion region FD1, the second floating diffusion region FD2, the source-follower transistor SF, and the second switch transistor SW2. In addition, the sub-active regions 220 formed on the sub-substrate 207 may provide active regions of the first switch transistor SW1, the reset transistor RX, and the select transistor SEL.

A first transmission gate TG1 and a second transmission gate TG2 may be formed on the main substrate 201 along with the first floating diffusion region FD1 and the second floating diffusion region FD2. The first transmission gate TG1 and the second transmission gate TG2 may each have a structure penetrating the main substrate 201. As illustrated in FIG. 5, the first transmission gate TG1 may include a transmission gate insulating layer 211 and a transmission gate electrode layer 212, and the second transmission gate TG2 may have a structure similar to that of the first transmission gate TG1.

A plurality of wiring patterns 230 including a contact 231 and a wiring 232 may be connected to the plurality of active regions 210 and 220 and the plurality of gates 215. The plurality of wiring patterns 230 may be disposed in the interlayer insulating layer 240 on the first surface S1. In addition, an optical region including a horizontal insulating layer 250, a color filter layer 260, and a micro lens 270 may be disposed on the second surface S2 of the main substrate 201. The structure of the optical region may be similar to that described above with reference to FIG. 5, and thus, the description may be omitted or briefly discussed.

Referring to FIGS. 7 and 8, the first floating diffusion region FD1 may be provided by a first active region, and the second floating diffusion region FD2 may include a second active region. The first floating diffusion region FD1 may overlap the first photodiode PD1, and the second floating diffusion region FD2 may overlap the second photodiode PD2. In addition, the second floating diffusion region FD2 may be electrically connected to one of the active regions of the second switch transistor SW2. The other of the active regions of the second switch transistor SW2 may be electrically connected to a third active region that is one of the sub-active regions 220, by one of the plurality of wiring patterns 230. In an example embodiment illustrated in FIGS. 7 and 8, the third active region may be an active region shared by the first switch transistor SW1 and the reset transistor RX.

In an example embodiment of the present inventive concept, the first switch transistor SW1 and the reset transistor RX may be formed on the sub-substrate 207, thereby blocking unintentional transfer of the electric charges between the first photodiode PD1 and the second photodiode PD2. For example, when the first switch transistor SW1 and the reset transistor RX1 are formed on the main substrate 201, the electric charges generated from the first photodiode PD1 may flow into the second photodiode PD2 through the third active region, the wiring pattern 230, and the active region of the second switch transistor SW2.

In addition, in an example embodiment of the present inventive concept, since the first switch transistor SW1 and the reset transistor RX1 are formed on the sub-substrate 207, a path through which the electric charges generated from the first photodiode PD1 is transferred to the third active region may be blocked by the insulating layer of the sub-substrate 207. The signal-to-noise ratio of the image sensor may be improved by blocking a path through which the electric charge of the first photodiode PD1 may be transferred to the second photodiode PD2.

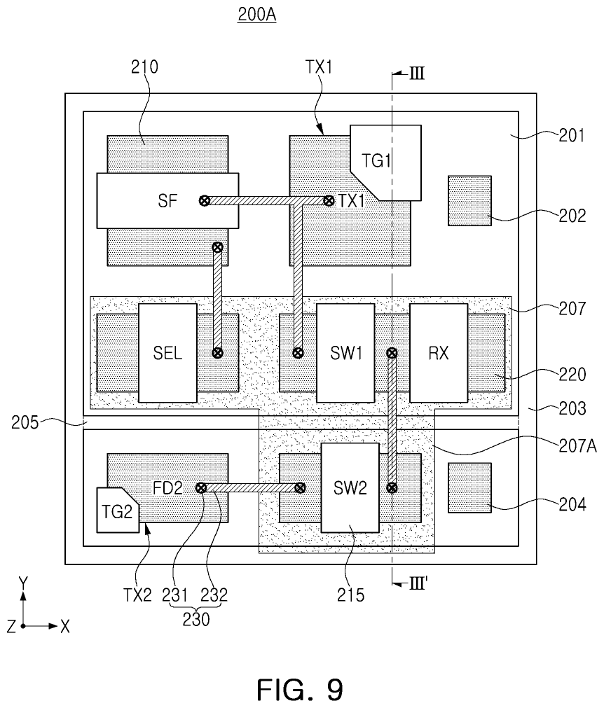

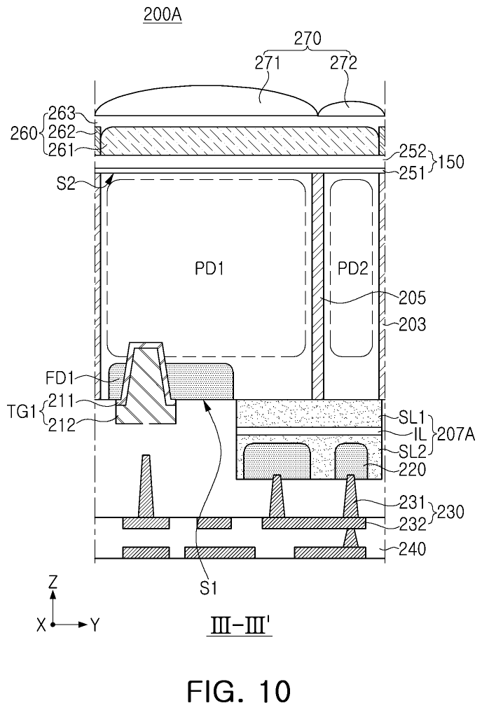

FIG. 9 is a diagram schematically illustrating pixels included in an image sensor according to an example embodiment of the present inventive concept. In addition, FIG. 10 is a cross-sectional view illustrating a cross-section taken along line III-III′ of FIG. 9.

A pixel 200A of the image sensor according to an example embodiment illustrated in FIGS. 9 and 10 may have a structure similar to that of the pixel 200 according to an example embodiment described with reference to FIGS. 7 and 8. However, in an example embodiment illustrated in FIGS. 9 and 10, a sub-substrate 207A may have a relatively large area as compared to the example embodiment illustrated in FIGS. 7 and 8. Referring to FIGS. 9 and 10, in addition to the select transistor SEL, the first switch transistor SW1, and the reset transistor RX, the second switch transistor SW2 may also be formed on the sub-substrate 207A. Accordingly, a partial region of the sub-substrate 207A may be disposed to overlap the internal separation film 205.

According to a principle similar to those described with reference to FIGS. 7 and 8, the electric charge transfer between the first photodiode PD1 and the second photodiode PD2 may be blocked in the pixel 200A. For example, a path through which the electric charges, which are generated from the first photodiode PD1, are transferred to one of the active regions, which provide the first switch transistor SW1 and the reset transistor RX, may be blocked by the insulating layer of the sub-substrate 207A. In addition, a path through which the electric charges generated from the second photodiode PD2 are transferred to one of the active regions of the second switch transistor SW2 may also be blocked by the insulating layer of the sub-substrate 207A. Accordingly, a signal-to-noise ratio of a first pixel signal corresponding to the electric charges of the first photodiode PD1 and a second pixel signal corresponding to the electric charges of the second photodiode PD2 may be improved.

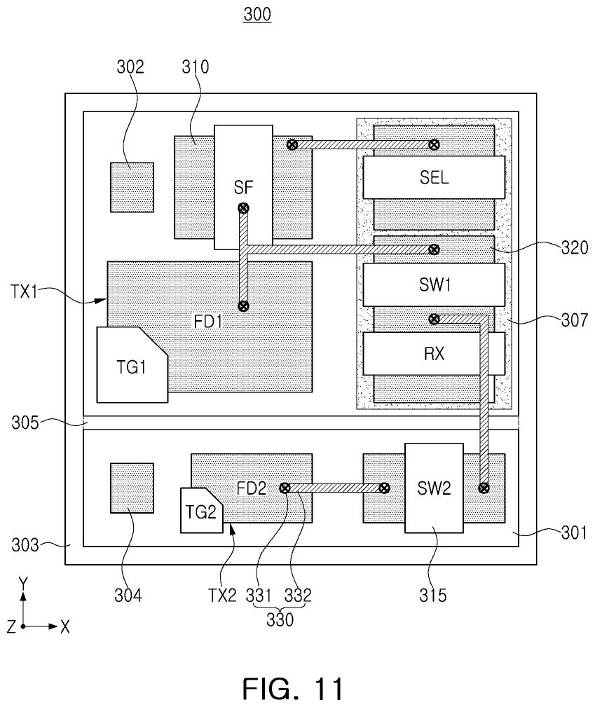

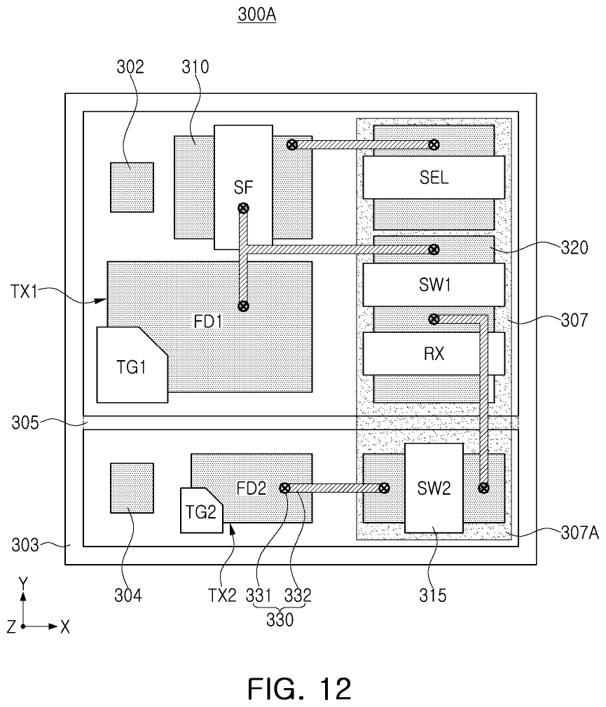

FIGS. 11 and 12 are simply diagrams illustrating pixels included in an image sensor according to an example embodiment of the present inventive concept.

In each of the example embodiments illustrated in FIGS. 11 and 12, a layout of pixels 300 and 300A of the image sensor may be different from the layout of the pixels 100, 200, and 200A according to the other example embodiments described above. For example, referring to FIGS. 11 and 12, in the pixels 300 and 300A, a sub-substrate 307 may be disposed adjacent to the source-follower transistor SF and the first floating diffusion region FD1 in the first direction (e.g., the X-axis direction), and a length of the sub-substrate 307 in the first direction (e.g., the X-axis direction) may be shorter than a length thereof in the second direction (e.g., the Y-axis direction). In addition, the source-follower transistor SF and the first floating diffusion region FD1 may be disposed adjacent to each other in the second direction.

Referring to FIG. 11, a pixel 300 may be separated from other peripheral pixels by the pixel separation film 303 formed on the main substrate 201, and the first photodiode and the second photodiode may be separated from each other by an internal separation film 305 that is disposed in the pixel 300. The pixel 300 may include a plurality of transistors provided by a plurality of active regions 310 and 320 and a plurality of gates 315. Among the plurality of transistors, a first transmission transistor TX1, a second transmission transistor TX2, a source-follower transistor SF, and a second switch transistor SW2 may be formed on the main substrate 301, and a select transistor SEL, a reset transistor RX, and a first switch transistor SW1 may be formed on the sub-substrate 307. The plurality of transistors may be connected to each other by a plurality of wiring patterns 330 including a contact 331 and a wiring 332 and may provide a pixel circuit.

Referring to FIG. 12, a sub-substrate 307A may have a longer length in the second direction than that of the embodiment illustrated in FIG. 11. Accordingly, a partial region of the sub-substrate 307A may overlap an internal separation film 305, and the second switch transistor SW2 may be formed on the sub-substrate 307A, in addition to the select transistor SEL, the reset transistor RX, and the first switch transistor SW1.

In each of embodiments illustrated in FIGS. 11 and 12, the electric charge transfer between the first and second photodiodes, which are separated from each other by the internal separation film 305, may be blocked by the sub-substrates 307 and 307A. As illustrated in FIGS. 11 and 12, one of the active regions included in the second switch transistor SW2 may be electrically connected to an active region, which is shared by the first switch transistor SW1 and the reset transistor RX, by a wiring pattern 330.

Accordingly, when both the active region shared by the first switch transistor SW1 and the reset transistor RX and the active region of the second switch transistor SW2 are formed on the main substrate 301, a path through which the electric charges generated from the first photodiode are transferred to the second photodiode may be formed. In an example embodiment illustrated in FIG. 11, the first switch transistor SW1 and the reset transistor RX may be formed on the sub-substrate 307 that is an SOI substrate, thereby preventing the electric charges generated from the first photodiode from being transferred to the active region shared by the first switch transistor SW1 and the reset transistor RX. In addition, in an example embodiment illustrated in FIG. 12, the first switch transistor SW1, the reset transistor RX, and the second switch transistor SW2 may be formed on the sub-substrate 307, thereby blocking the path through which the electric charges that are generated from the first photodiode are transferred to the second photodiode through the active regions 310 and 320 and the wiring pattern 330.

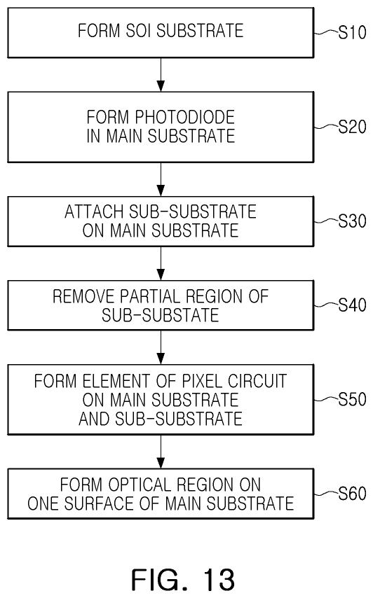

FIG. 13 is a flowchart illustrating a manufacturing method of an image sensor according to an example embodiment of the present inventive concept.

Referring to FIG. 13, a manufacturing method of an image sensor according to an example embodiment of the present inventive concept may be initiated by forming an SOI substrate (S10). For example, the SOI substrate may be manufactured by using two semiconductor substrates including a semiconductor material. The SOI substrate may be manufactured by forming an insulating layer on a first semiconductor substrate, attaching a second semiconductor substrate onto the insulating layer, and then removing a portion of the second semiconductor substrate.

While manufacturing the SOI substrate, a plurality of photodiodes may be formed on the main substrate (S20). For example, a pixel separation film forming a plurality of pixel regions may be formed on the main substrate, and the plurality of photodiodes may be formed such that at least one photodiode is disposed in each of the plurality of pixel regions. The plurality of photodiodes may be formed by an ion implantation process. According to an example embodiment of the present inventive concept, two or more photodiodes may be formed in each of the plurality of pixel regions.

When the pixel separation film and the plurality of photodiodes are formed on the main substrate, a sub-substrate may be attached to the main substrate (S30). The sub-substrate attached to the main substrate in operation S30 may be the SOI substrate manufactured in operation S10. The sub-substrate is attached to a first surface of the main substrate, and for example, the first surface may be a surface into which ions are implanted to form the plurality of photodiodes. When the sub-substrate is attached to the main substrate, a portion of the first surface of the main substrate may be exposed by removing a portion of the sub-substrate (S40).

Then, elements included in a pixel circuit may be formed on the main substrate and the sub-substrate (S50). For example, the elements providing the pixel circuit may include a transmission transistor, a source-follower transistor, a reset transistor, a select transistor, and switch transistors. The switch transistor may be connected between floating diffusion regions that are for storing electric charges of each of the plurality of photodiodes disposed in one pixel region. In an example embodiment of the present inventive concept, at least one of the switch transistors may be formed on the sub-substrate. Accordingly, a path through which the electrical charges may be transferred between the photodiodes included in one pixel region may be blocked by the insulating layer included in the sub-substrate.

When all the elements included in the pixel circuit are formed, an optical region may be formed on one surface of the main substrate (S60). The optical region includes a plurality of color filters, a plurality of micro lenses, and a horizontal insulating layer, and may be formed on a second surface facing the first surface, to which the sub-substrate is attached, of the main substrate. According to an example embodiment of the present inventive concept, a process of removing a partial region of the main substrate from the second surface of the main substrate may be first performed before forming the optical region.

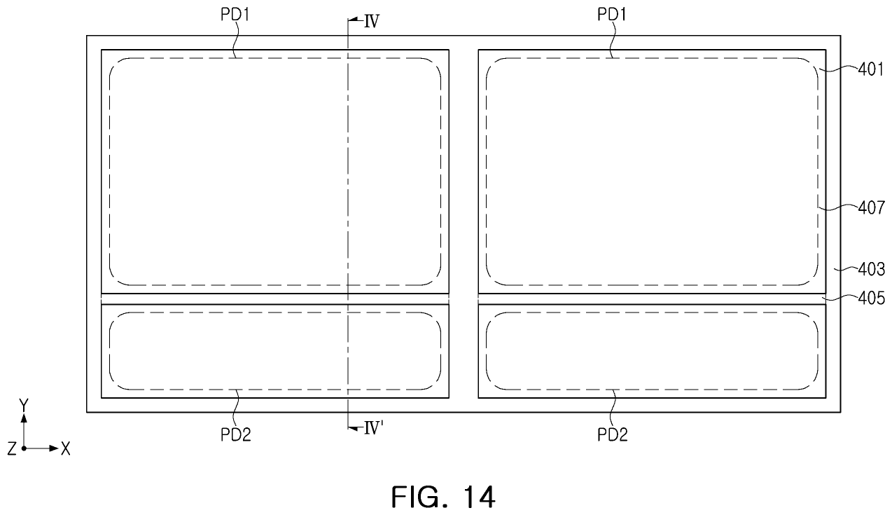

FIGS. 14 to 23 are intermediate steps illustrating the manufacturing method of an image sensor according to an example embodiment of the present inventive concept.

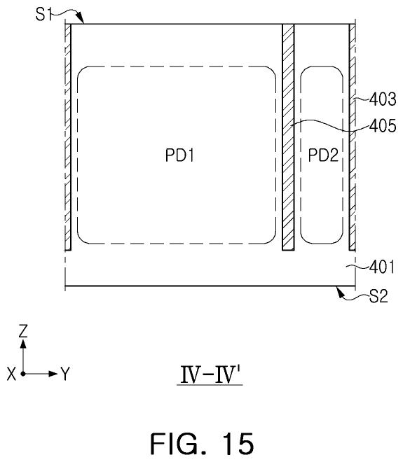

First, referring to FIG. 14 and FIG. 15 illustrating cross-sections taken along line IV-IV′ of FIG. 14, a pixel separation film 403 and an internal separation film 405 may be formed on the main substrate 401. The pixel separation film 403 may define a plurality of pixel regions PX1 and PX2, and the internal separation film 405 may be disposed inside each of the plurality of pixel regions PX1 and PX2. The pixel separation film 403 may extend in the first direction (e.g., the X-axis direction) and the second direction (e.g., the Y-axis direction) and may distinguish the plurality of pixel regions PX1 and PX2 from each other. The pixel separation film 403 and the internal separation film 405 may be formed to have a smaller depth than a thickness of the main substrate 401. For example, the pixel separation film 403 and the internal separation film 405 might not completely penetrate the main substrate 401. The pixel separation film 403 and the internal separation film 405 may be formed of an insulating material.

In addition, photodiodes PD1 and PD2 may be formed in regions defined by the pixel separation film 403 and the internal separation film 405. In an example embodiment illustrated in FIGS. 14 and 15, the first photodiode PD1 and the second photodiode PD2 may be formed in each of the plurality of pixel regions PX1 and PX2. A light receiving area of the first photodiode PD1 may be larger than a light receiving area of the second photodiode PD2.

For example, each of the first photodiode PD1 and the second photodiode PD2 may be formed by an ion implantation process of implanting an N-type impurity through the first surface S1 with respect to the main substrate 401 including a P-type impurity. For example, an electric charge blocking region doped with the P-type impurity may be formed around the pixel separation film 403 and the internal separation film 405 so that the photodiodes PD1 and PD2 are electrically separated from each other more clearly by the pixel separation film 403 and the internal separation film 405.

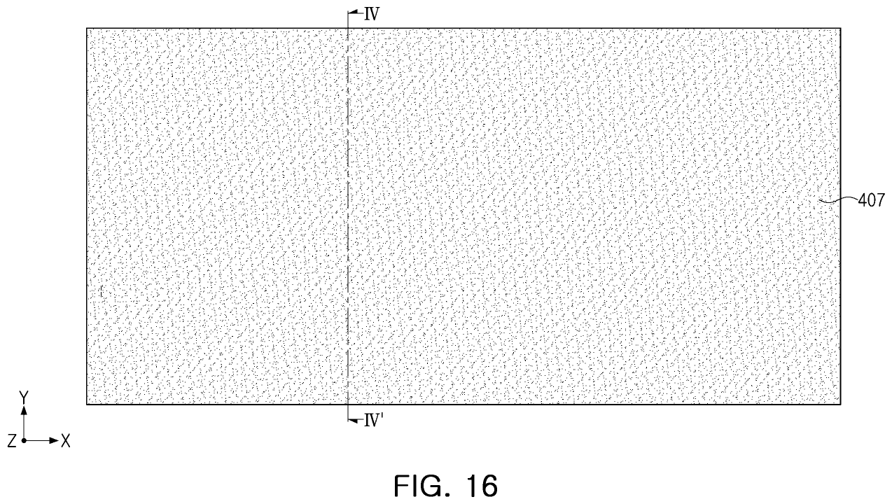

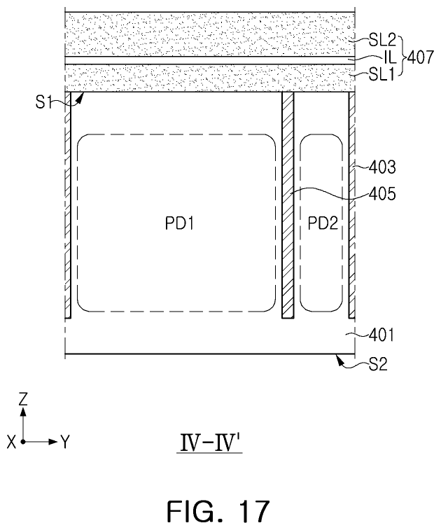

Next, referring to FIG. 16 and FIG. 17 illustrating a cross-section taken along line IV-IV′ of FIG. 16, a sub-substrate 407 may be attached to a first surface S1 of the main substrate 401. The sub-substrate 407 may be an SOI substrate including a first semiconductor layer SL1, an insulating layer IL, and a second semiconductor layer SL2. For example, the sub-substrate 407 may be attached to cover the entire first surface of the main substrate 401.

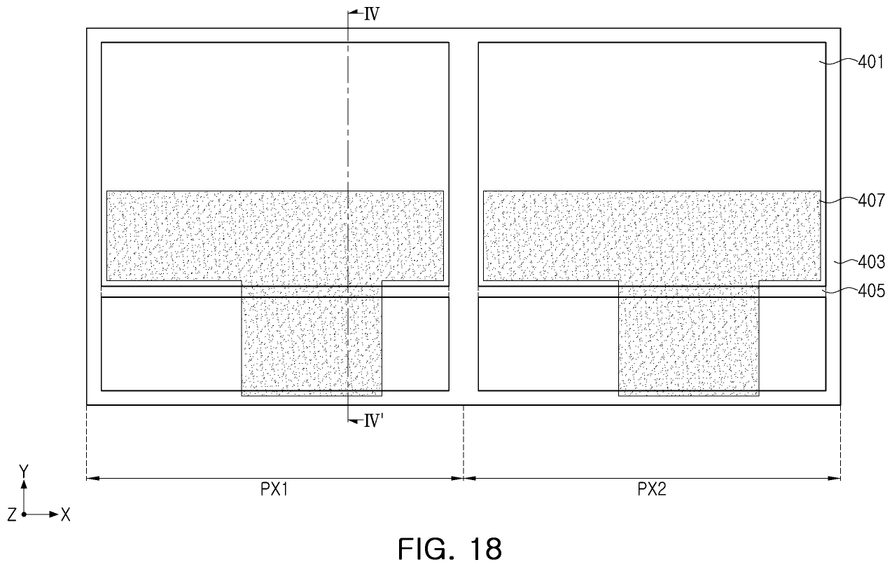

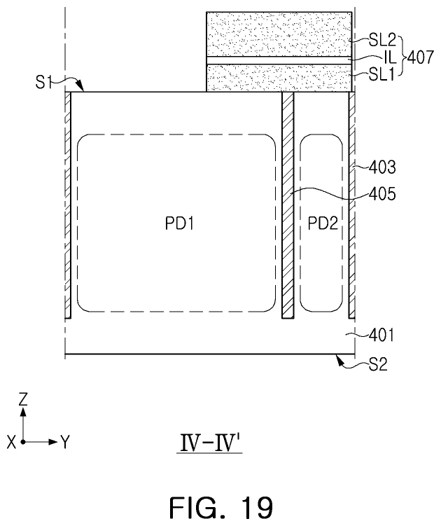

Referring to FIGS. 18 and 19, a portion of the first surface S1 of the main substrate 401 may be exposed by removing a portion of the sub-substrate 407. In an example embodiment illustrated in FIGS. 18 and 19, the sub-substrate 407 may overlap a portion of the internal separation film 405 that is disposed in each of the plurality of pixel regions PX1 and PX2. The area and shape of the sub-substrate 407 remaining in each of the plurality of pixel regions PX1 and PX2 may vary according to the layout of elements disposed in each of the plurality of pixel regions PX1 and PX2.

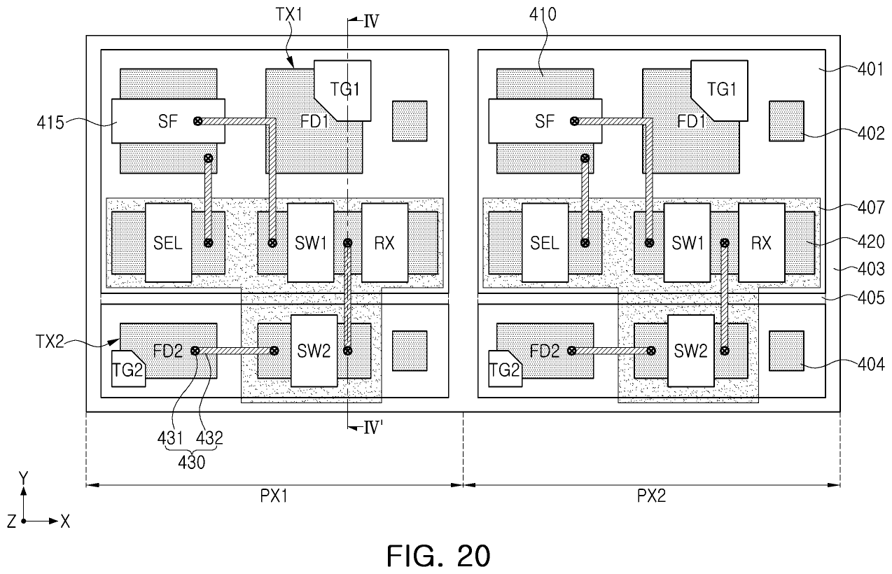

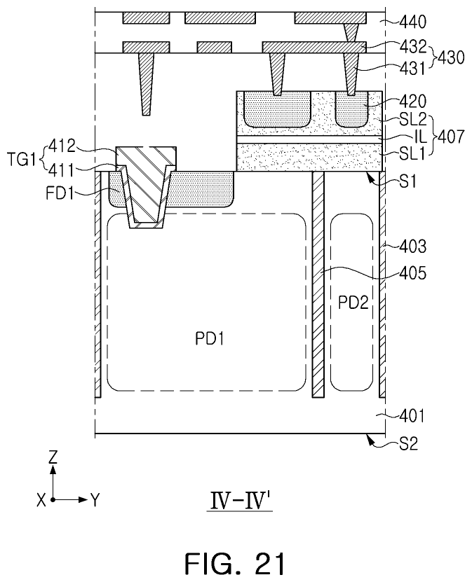

Next, referring to FIGS. 20 and 21, elements, which are connected to the first photodiode PD1 and the second photodiode PD2 in each of the plurality of pixel regions PX1 and PX2 and are configured to provide a pixel circuit, may be formed on the main substrate 401 and the sub-substrate 407. The elements include a plurality of transistors provided by a plurality of active regions 410 and 420 and a plurality of gates 415. The plurality of transistors may be connected to each other by a plurality of wiring patterns 430 including a contact 431 and a wiring 432 and may provide the pixel circuit. The plurality of transistors may include a first transmission transistor TX1, a second transmission transistor TX2, a source-follower transistor SF, a select transistor SEL, a reset transistor RX, a first switch transistor SW1, and a second switch transistor SW2. In addition, power regions 402 and 404 that are doped with impurities may be formed on the main substrate 401 to provide a power voltage.

Referring to FIGS. 20 and 21, the first transmission transistor TX1, the second transmission transistor TX2, and the source-follower transistor SF may be formed on the main substrate 401, and the select transistor SEL, the reset transistor RX, the first switch transistor SW1, and the second switch transistor SW2 may be formed on the sub-substrate 407. As illustrated in FIG. 21, a first transmission gate TG1 configured to provide the first transmission transistor TX1 may include a transmission gate insulating layer 411 and a transmission gate electrode layer 412 having a region embedded in the main substrate 401. A structure of a second transmission gate TG2 may be similar to a structure of the first transmission gate TG1.

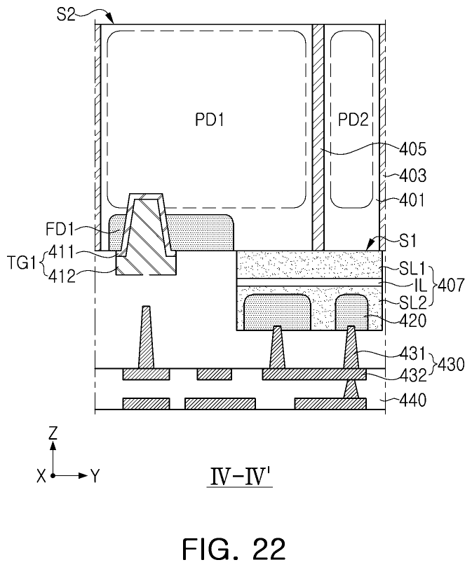

At least one of the first switch transistor SW1 and the second switch transistor SW2 may be formed on the sub-substrate 407, thereby preventing the electric charges generated from the first photodiode PD1 and the second photodiode PD2 from being transferred to each other during the exposure time. For example, when both the first switch transistor SW1 and the second switch transistor SW2 are formed on the main substrate 401, the electric charges generated from the first photodiode PD1 may be transferred to the second photodiode PD2 through the active regions of each of the first switch transistor SW1 and the second switch transistor SW2. On the other hand, in an example embodiment of the present inventive concept, the electric charge transfer may be blocked by the insulating layer IL of the sub-substrate 407 on which the first switch transistor SW1 and the second switch transistor SW2 are formed. When the plurality of transistors providing a pixel circuit are formed, a portion of the main substrate 401 may be removed from the second surface S2 as illustrated in FIG. 22. For example, after the process described with reference to FIGS. 20 and 21 is completed, the main substrate 401 may be inverted, and a polishing process may be then advanced in a state in which the second surface S2 is exposed, thus reducing a thickness of the main substrate 401. For example, the thickness of the main substrate 401 after completing the polishing process may be equal to the depth of the pixel separation film 403 and the internal separation film 405. Accordingly, as illustrated in FIG. 22, the pixel separation film 403 and the internal separation film 405 may extend from the first surface S1 to the second surface S2 of the main substrate 401.

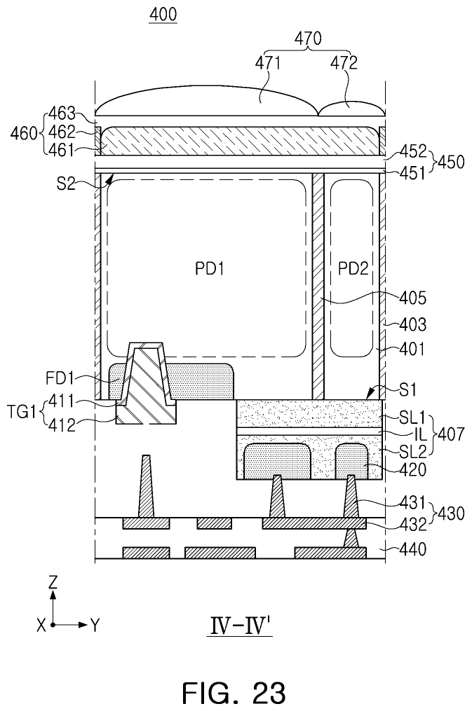

Next, referring to FIG. 23, an optical region may be formed on the second surface S2 of the main substrate 401. The optical region may include a horizontal insulating layer 450, a color filter layer 460, and a micro lens 470. The horizontal insulating layer 450 may include a first horizontal insulating layer 451 and a second horizontal insulating layer 452, and for example, the first horizontal insulating layer 451, which is in contact with the main substrate 401, may have a higher dielectric constant than that of the second horizontal insulating layer 452. The first horizontal insulating layer 451 may be formed of a high dielectric constant material, thereby curing a portion of defects of the main substrate 401 caused by a polishing process.

The color filter layer 460 may include a color filter 461, a filter separation film 462, and a planarization layer 463. The filter separation film 462 is disposed over the pixel separation film 403, and the color filter 461 may be arranged along the plurality of pixel regions PX1 and PX2 by the filter separation film 462. The planarization layer 463 may be disposed on the color filter 461, and the micro lens 470 may be disposed on the planarization layer 463. For example, the planarization layer 463 may be disposed on the filter separation film 462. The micro lens 470 may include a first micro lens 471, which is disposed over the first photodiode PD1, and a second micro lens 472, which is disposed over the second photodiode PD2 in each of the plurality of pixel regions PX1 and PX2. However, according to an example embodiment of the present inventive concept, one micro lens may be disposed in each of the plurality of pixel regions PX1 and PX2.

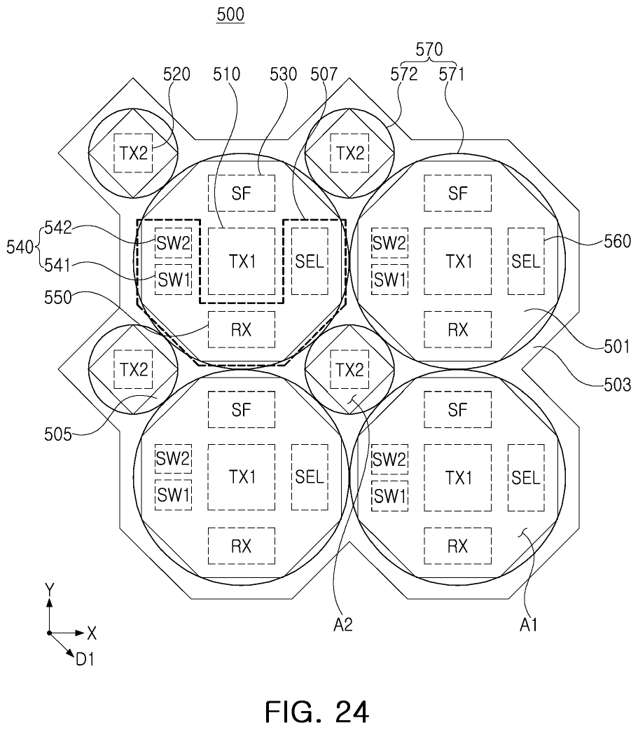

FIG. 24 is a diagram schematically illustrating pixels included in an image sensor according to an example embodiment of the present inventive concept.

Referring to FIG. 24, each of a plurality of pixels included in an image sensor 500 according to an example embodiment of the present inventive concept may be separated from each other by a pixel separation film 503. Each of the plurality of pixels may include a first region A1 and a second region A2 disposed adjacent to each other in a diagonal direction D1. A first photodiode may be disposed in the first region A1, and a second photodiode may be disposed in the second region A2. The first region A1 and the second region A2 are separated from each other by an internal separation film 505, and a light receiving area of the first photodiode may be larger than a light receiving area of the second photodiode. The diagonal direction D1 may be a direction crossing the first direction (e.g., the X-axis direction) and the second direction (e.g., the Y-axis direction).

Each of the plurality of pixels may include a plurality of transistors. The plurality of transistors may include a first transmission transistor TX1, a second transmission transistor TX2, a source-follower transistor SF, a select transistor SEL, a reset transistor RX, a first switch transistor SW1, and a second switch transistor SW2. In addition to the plurality of transistors, each of the plurality of pixels may further include a capacitor element. A pixel circuit of each of the plurality of pixels may be the same as the pixel circuit described above with reference to FIG. 2.

The plurality of transistors may be disposed in a plurality of element regions 510 to 560. Each of the plurality of element regions 510 to 560 may include at least one active region and a gate. For example, a first transmission gate and a first floating diffusion region may be disposed in the first element region 510, and a second transmission gate and a second floating diffusion region may be disposed in the second element region 520.

In an example embodiment illustrated in FIG. 24, the image sensor 500 may include a main substrate 501 and a sub-substrate 507 attached to one surface of the main substrate 501. The sub-substrate 507 may be, for example, an SOI substrate. Referring to FIG. 24, some transistors among the plurality of transistors may be disposed on the main substrate 501, and the other transistors among the plurality of transistors may be disposed on the sub-substrate 507.

For example, the first to third element regions 510 to 530 may be disposed on the main substrate 501, and the fourth to sixth element regions 540 to 560 may be disposed on the sub-substrate 507. Accordingly, the first transmission transistor TX1, the second transmission transistor TX2, and the source-follower transistor SF may be disposed on the main substrate 501, and the select transistor SEL, the reset transistor RX, the first switch transistor SW1, and the second switch transistor SW2 may be disposed on the sub-substrate 507.

The second floating diffusion region, which is disposed in the second element region 520, may be connected to one of the active regions of the second switch transistor SW2 through a wiring pattern. In an example embodiment of the present inventive concept, the second switch transistor SW2 may be formed on the sub-substrate 507 that is an SOI substrate. Accordingly, electric charges of the first photodiode, which is disposed below the second switch transistor SW2, may be prevented from flowing into the second floating diffusion region and the second photodiode through one of the active regions of the second switch transistor SW2, thereby improving a signal-to-noise ratio of the image sensor 500.

While the present inventive concept has been described with reference to embodiments thereof, it will be understood by those of ordinary skill in the art that various changes in form and details may be made thereto without departing from the spirit and scope of the present inventive concept.

What is claimed is:

1. An image sensor comprising:
a pixel array in which a plurality of pixels are arranged, wherein each of the plurality of pixels includes a first photodiode, a second photodiode, a first transmission gate, a second transmission gate, and a plurality of active regions; and
a logic circuit configured to control the plurality of pixels,
wherein a light receiving area of the first photodiode is larger than a light receiving area of the second photodiode,
the plurality of active regions include a first active region, a second active region and a third active region, wherein the first active region is disposed adjacent to the first transmission gate, wherein the second active region is disposed adjacent to the second transmission gate, wherein the third active region is electrically connected to the second active region by a wiring pattern, and
the first active region and the second active region are disposed on a main substrate, which includes the first photodiode and the second photodiode, and the third active region is disposed on a sub-substrate that is attached to the main substrate.

2. The image sensor of claim 1, wherein the sub-substrate is a silicon on insulator (SOI) substrate.

3. The image sensor of claim 2, wherein a thickness of the sub-substrate is less than a thickness of the main substrate.

4. The image sensor of claim 1, wherein the first active region provides a first floating diffusion region, and the second active region and the third active region provide a second floating diffusion region, and
the third active region is disposed on the first photodiode in a direction substantially perpendicular to a first surface of the main substrate.

5. The image sensor of claim 1, wherein each of the plurality of pixels includes a plurality of switch transistors and at least one source-follower transistor, and
the at least one source-follower transistor is disposed on the main substrate.

6. The image sensor of claim 5, wherein the plurality of switch transistors are disposed on the sub-substrate.

7. The image sensor of claim 1, wherein each of the plurality of pixels further includes a first micro lens, a second micro lens, and an internal separation film, wherein the first micro lens is attached to a second surface of the main substrate and is disposed on the first photodiode, wherein the second micro lens is attached to the second surface of the main substrate and is disposed on the second photodiode, wherein the internal separation film is disposed between the first photodiode and the second photodiode.

8. The image sensor of claim 7, wherein the internal separation film extends from the first surface to the second surface of the main substrate.

9. The image sensor of claim 7, wherein at least a portion of the sub-substrate overlaps the internal separation film.

10. The image sensor of claim 1, wherein each of the plurality of pixels further includes a capacitor element that is connected to the second active region.

11. The image sensor of claim 1, wherein the pixel array further includes a pixel separation film and a charge blocking region, wherein the pixel separation film is disposed between the plurality of pixels, and the charge blocking region is disposed around the pixel separation film, and
the charge blocking region is doped with a conductive type impurity that is different from that of the photodiode.

12. The image sensor of claim 1, wherein in a direction substantially perpendicular to a first surface of the main substrate, the sub-substrate overlaps the first photodiode and does not overlap the second photodiode.

13. An image sensor comprising:
a main substrate including a plurality of pixel regions and a plurality of photodiodes, wherein the plurality of pixel regions is separated from each other by a pixel separation film, and the plurality of photodiodes is disposed in the plurality of pixel regions;
a sub-substrate disposed on a first surface of the main substrate;
an optical region disposed on a second surface of the main substrate and including a plurality of color filters and a plurality of micro lenses,
wherein some transistor among a plurality of transistors included in each of the plurality of pixel regions are disposed on the main substrate, and the other transistors among the plurality of transistors are disposed on the sub-substrate, and
the some transistors and the other transistors do not overlap each other in a direction substantially perpendicular to the first surface of the main substrate.

14. The image sensor of claim 13, wherein the plurality of transistors include a plurality of transmission transistors, a plurality of switch transistors, and at least one source-follower transistor, and
the plurality of transmission transistors and the at least one source-follower transistor are disposed on the main substrate, and the plurality of switch transistors are disposed on the sub-substrate.

15. The image sensor of claim 13, wherein the plurality of transistors include a plurality of transmission transistors, a plurality of switch transistors, and a select transistor, and
the plurality of transmission transistors are disposed on the main substrate, and the select transistor and the plurality of switch transistors are disposed on the sub-substrate.

16. The image sensor of claim 13, wherein in each of the plurality of pixel regions, the some transistors and the other transistors are disposed at different positions from each other on a plane that is parallel to an upper surface of the main substrate.

17. The image sensor of claim 13, wherein the plurality of transistors include a select transistor, a reset transistor, a first switch transistor, and a second switch transistor, wherein the select transistor is connected between at least one source-follower transistor and a column line, wherein the reset transistor is connected to a power node, wherein the first switch transistor is connected between a gate of the source-follower transistor and the reset transistor, and wherein the second switch transistor is connected to a node that is between the reset transistor and the first switch transistor.

18. The image sensor of claim 13, wherein the plurality of photodiodes include a plurality of first photodiodes and a plurality of second photodiodes, and
one of the plurality of first photodiodes and one of the plurality of second photodiodes are disposed in each of the plurality of pixel regions.

19. The image sensor of claim 18, wherein a light receiving area of each of the plurality of first photodiodes is larger than a light receiving area of each of the plurality of second photodiodes.

20. A manufacturing method of an image sensor, the method comprising:
forming a pixel separation film, which is configured to separate a plurality of pixel regions, on a main substrate;
forming a plurality of photodiodes on the main substrate;
attaching a sub-substrate to the main substrate;
removing a partial region of the sub-substrate;
forming a plurality of semiconductor elements on the main substrate and the sub-substrate; and
forming a plurality of color filters and a plurality of micro lenses on the main substrate.

21. The manufacturing method of an image sensor of claim 20, wherein the plurality of semiconductor elements include a plurality of transmission transistors, a plurality of switch transistors, and at least one source-follower transistor in each of the plurality of pixel regions, and
the plurality of transmission transistors and the at least one source-follower transistor are formed on the main substrate, and the plurality of switch transistors are formed on the sub-substrate.

22. The manufacturing method of an image sensor of claim 20, wherein in the forming the plurality of semiconductor elements, a plurality of active regions are formed in each of the main substrate and the sub-substrate, and
at least one of the plurality of active regions that are formed in the main substrate is connected to at least one of the plurality of active regions that are formed in the sub-substrate by a wiring pattern.

23. The manufacturing method of an image sensor of claim 20, wherein in each of the plurality of pixel regions, an area of a region in which the sub-substrate remains is smaller than an area of a region from which the sub-substrate is removed.
